(19) United States
(12) Patent Application Publication
(10) Pub. No.: US 2023/0091120 A1
(43) Pub. Date: Mar. 23, 2023

(54) Cleaning System

(71) Applicant: Daifuku Co., Ltd., Osaka-shi (JP)

(72) Inventors: Koichi Hagiwara, Komaki-shi (JP); Tsuyoshi Uemura, Hinocho (JP)

(21) Appl. No.: 17/945,441

(22) Filed: Sep. 15, 2022

(30) Foreign Application Priority Data
Sep. 16, 2021 (JP) 2021-150942

(51) Int. Cl. A47L 9/28; G05D 1/02

(52) U.S. Cl. CPC A47L 9/281; A47L 9/2852; G05D 1/0219; A47L 2201/04; A47L 2201/06; B61B 3/02

(57) ABSTRACT

A cleaning system includes a cleaning vehicle that cleans a predetermined travel route, and a control device. The cleaning vehicle includes a state detection device that detects a state of the travel route, and has a cleaning mode in which the cleaning is performed and a non-cleaning mode in which the cleaning is not performed. The control device executes inspection control for causing the state detection device to detect a state of a pre-set inspection region along the travel route while causing the cleaning vehicle to travel in the non-cleaning mode, specification control for specifying a cleaning required region, where the cleaning needs to be performed in the travel route, based on the state of the inspection region detected in the inspection control, and cleaning control for causing the cleaning vehicle to travel in the cleaning mode in the cleaning required region after the above-mentioned controls end.

### CROSS-REFERENCE TO RELATED APPLICATION

This application claims priority to Japanese Patent Application No. 2021-150942 filed Sep. 16, 2021, the disclosure of which is hereby incorporated by reference in its entirety.

### BACKGROUND OF THE INVENTION

### Field of the Invention

The present invention relates to a cleaning system that includes a cleaning vehicle that travels along a defined travel route and cleans the travel route.

### Description of the Related Art

An example of such a cleaning system is disclosed in Japanese Laid-Open Patent Publication No. 2013-605 (hereinafter referred to as “Patent Document 1”). In the cleaning system of Patent Document 1, a cleaning vehicle (W) cleans a travel route (L) by suctioning dust that has accumulated along the travel route (L). Note that the reference numerals in parentheses in the description of the related art are those used Patent Document 1.

Patent Document 1 does not particularly mention a condition according to which the cleaning vehicle (W) cleans the travel route (L). For this reason, the travel route (L) is cleaned even in the case where the amount of dust that has accumulated on the travel route (L) is very small, for example. As a result, there have been cases where the cleaning of the travel route (L) becomes inefficient, such as the case of cleaning a region that does not need to be cleaned along the travel route (L). For example, if a region in which cleaning needs to be performed along the travel route (L) is identified visually, for example, by a worker, and the worker manually sets the region to be cleaned by the cleaning vehicle (W), it is possible to avoid inefficient cleaning of the travel route (L), but this has a disadvantage of an increased burden on the worker.

### SUMMARY OF THE INVENTION

In view of foregoing, there is desire for the realization of a cleaning system in which cleaning can be performed automatically and efficiently by a cleaning vehicle.

Additionally, in view of the foregoing, a characteristic configuration of a cleaning system includes:

a cleaning vehicle configured to travel along a predetermined travel route and clean the travel route; and

a control device configured to control the cleaning vehicle,

wherein the cleaning vehicle includes a state detection device configured to detect a state of the travel route, and has, as operation modes, a cleaning mode in which the cleaning is performed and a non-cleaning mode in which the cleaning is not performed, and

the control device is configured to execute:
an inspection control of causing the state detection device to detect a state of a pre-set inspection region along the travel route while causing the cleaning vehicle to travel in the non-cleaning mode;
a specification control of specifying a cleaning required region, which is a region in which the cleaning needs to be performed in the travel route, based on the state of the inspection region detected by the state detection device in the inspection control; and
a cleaning control of causing the cleaning vehicle to travel in the cleaning mode in the cleaning required region after the inspection control and the specification control end.

According to this characteristic configuration, the state of the pre-set inspection region along the travel route is detected by the state detection device provided in the cleaning vehicle. A cleaning required region, which is a region in which cleaning needs to be performed along the travel route, is specified based on the state of the inspection region detected by the state detection device, and the cleaning vehicle is caused to perform cleaning in the cleaning required region. This eliminates the need for a worker to identify a cleaning required region visually, for example, or manually set the region to be cleaned by the cleaning vehicle. Accordingly, the cleaning performed by the cleaning vehicle can be performed automatically and efficiently.

### BRIEF DESCRIPTION OF THE DRAWINGS

FIG. 1 is a schematic diagram showing an overall configuration of an article transport facility provided with a cleaning system according to an embodiment.

FIG. 2 is a side view of a cleaning vehicle and a transport vehicle.

FIG. 3 is a control block diagram of the article transport facility provided with the cleaning system according to the embodiment.

FIG. 4 is a flowchart showing an example of control processing performed by a control device.

FIG. 5 is a diagram showing a first processed image, which is an image obtained by performing grayscale processing on a captured image acquired by a state detection device.

FIG. 6 is a diagram showing a second processed image, which is an image obtained by performing binarization processing on the first processed image.

FIG. 7 is a diagram showing an example of cleaning required regions and a pre-cleaning movement route.

FIG. 8 is a diagram showing an example of contamination levels, pre-cleaning movement route lengths, and set cleaning counts for cleaning required regions.

### DESCRIPTION OF THE INVENTION

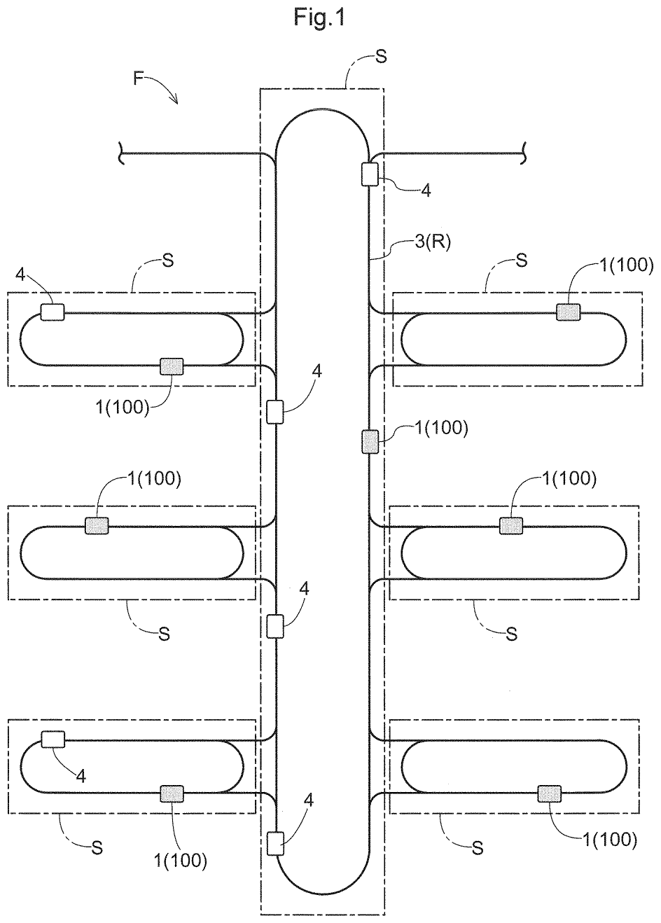

A cleaning system 100 according to an embodiment will be described below with reference to the drawings. As shown in FIG. 1, in the present embodiment, the cleaning system 100 is provided in an article transport facility F.

First, the article transport facility F will be described. The article transport facility F includes rails 3 and transport vehicles 4.

The rails 3 constitute a travel route R for the transport vehicles 4. In the present embodiment, the rails 3 are supported so as to be suspended from the ceiling of the article transport facility F.

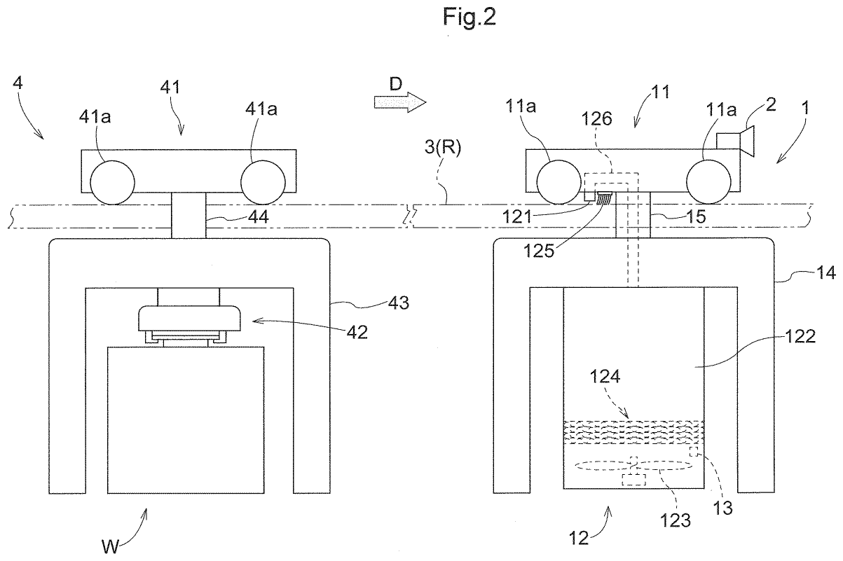

The transport vehicles 4 are configured to travel along the travel route R. In the present embodiment, a plurality of transport vehicles 4 are provided. The transport vehicles 4 are configured to transport articles W (see FIG. 2) to one of a plurality of transport target locations (not shown) arranged along the travel route R.

The articles W are each a FOUP (Front Opening Unified Pod) that houses a plurality of semiconductor wafers, for example. In this case, the transport vehicles 4 transport the articles W to transport target locations such as a processing device for processing semiconductor wafers or a storehouse for temporary storage.

As shown in FIG. 2, in the present embodiment, the transport vehicles 4 each include a first travel section 41, a transfer section 42, and a first cover 43.

The first travel section 41 includes a plurality of first wheels 41a that roll on the rails 3. In the present embodiment, at least one of the first wheels 41a is rotated by driving force from a travel motor (not shown) so as to roll on the rails 3, and thus the remaining first wheels 41a also move on the rails 3. In this way, the first travel section 41 travels along the travel route R configured by the rails 3.

The transfer section 42 transfers an article W to and from a transport target location. Although not described in detail here, the transfer section 42 includes a holding section for holding the article W, and an elevating section for lifting and lowering the holding section relative to the first travel section 41, for example. The transfer section 42 also includes a horizontal movement section that moves the holding section horizontally relative to the first travel section 41, and a turn section that rotates the holding section relative to the first travel section 41 about a rotation axis extending in the vertical direction. Note that the transfer section 42 need only have a configuration necessary for transferring an article W to and from a transport target location, and is not limited to having the above configuration.

The first cover 43 is formed to cover the article W held by the transfer section 42. In the present embodiment, the first cover 43 is formed so as to cover the article W from above and both sides in the traveling direction of the first travel section 41 (left-right direction in FIG. 2) when the article W is being held by the holding section while the holding section is located at the highest position in the range of movement by the elevating section. Also, in the present embodiment, the first cover 43 is coupled to the first travel section 41 via a first coupling section 44 so as to be suspended from the first travel section 41.

Next, the cleaning system 100 will be described. As shown in FIG. 1, the cleaning system 100 includes cleaning vehicles 1.

The cleaning vehicles 1 travel along a defined travel route R. The cleaning vehicles 1 clean the travel route R. A plurality of cleaning vehicles 1 are provided in the present embodiment. Also, in the present embodiment, the travel route R that is cleaned by the cleaning vehicles 1 is the travel route R along which the transport vehicles 4 travel. For this reason, the cleaning vehicles 1 and the transport vehicles 4 are configured to travel along a travel direction D on the same rails 3 that form the travel route R. In the present embodiment, the cleaning vehicles 1 clean dust that has accumulated on the rails 3. Such dust appears due to the operation of components in the article transport facility F, such as due to the wearing of the first wheels 41a when the transport vehicles 4 travel on the rails 3.

As shown in FIG. 2, in the present embodiment, each of the cleaning vehicles 1 includes a second travel section 11, a cleaning section 12, a dust amount detection section 13, and a second cover 14.

The second travel section 11 includes a plurality of second wheels 11a that roll on the rails 3. In the present embodiment, at least one of the second wheels 11a is rotated by driving force from a travel motor (not shown) so as to roll on the rails 3, and thus the remaining second wheels 11a also move on the rails 3. In this way, the second travel section 11 travels along the travel route R configured by the rails 3.

The cleaning section 12 includes a suction nozzle 121, a storage member 122, a fan 123, and a filter 124.

The suction nozzle 121 is a nozzle for suctioning dust that has accumulated on the rails 3. The suction nozzle 121 is arranged so as to face a dust accumulation location on the rails 3 (here, the upper surfaces of the rails 3). The suction nozzle 121 is fixed to the second travel section 11 so as to move together with the second travel section 11.

In the present embodiment, a brush member 125 is provided at a position adjacent to the suction nozzle 121 on the downstream side thereof in the traveling direction D. The brush member 125 is a group of bristles (e.g., synthetic fibers, carbon fibers, or metal fibers). The brush member 125 is arranged so as to come into contact with the dust accumulation location on the rails 3 (here, the upper surfaces of the rails 3). The brush member 125 is fixed to the second travel section 11 so as to move together with the second travel section 11. For this reason, dust that has accumulated on the rails 3 is removed from the rails 3 by the brush member 125 as the second travel section 11 travels along the rails 3. Dust removed from the rails 3 by the brush member 125 is suctioned by the suction nozzle 121.

The storage member 122 is configured to store dust suctioned by suction nozzle 121. In the present embodiment, the internal space of the storage member 122 and the suction nozzle 121 are in communication with each other via a pipe 126.

The fan 123 and the filter 124 are arranged in the internal space of the storage member 122. The fan 123 generates an airflow for allowing the suction nozzle 121 to suction dust that has accumulated on the rails 3. In the present embodiment, the airflow generated by the fan 123 flows through the suction nozzle 121, the pipe 126, and the internal space of the storage member 122 in this order. The filter 124 captures dust suctioned by the suction nozzle 121. In the present embodiment, the filter 124 is arranged upstream of the fan 123 in the direction of the airflow generated by the fan 123.

The dust amount detection section 13 is configured to detect the amount of dust collected by the cleaning section 12. In the present embodiment, the dust amount detection section 13 detects the amount of dust captured by the filter 124. In this example, the dust amount detection section 13 includes a pressure sensor that detects the pressure in the internal space of the storage member 122. Here, as the amount of dust captured by the filter 124 increases, it becomes more difficult for the airflow generated by fan 123 to pass through the filter 124, and thus the pressure difference between the spaces on opposite sides of filter 124 in the internal space of the storage member 122 increases. The dust amount detection section 13 detects the amount of dust captured by the filter 124 by detecting the pressure difference described above. In the example shown in FIG. 2, the dust amount detection section 13 is arranged in the internal space of the storage member 122, at a location downstream of the filter 124 in the flowing direction of the airflow generated by the fan 123. For this reason, the dust amount detection section 13 detects the amount of dust captured by the filter 124 by detecting a decrease in the pressure at a location downstream of the filter 124 in the internal space of the storage member 122. Note that any of various known types of sensors can be used as the pressure sensor included in the dust amount detection section 13.

The second cover 14 is formed so as to cover at least a portion of the cleaning section 12. In the present embodiment, the second cover 14 is formed so as to cover the storage member 122 of the cleaning section 12 from above and both sides in the traveling direction of the second travel section 11 (the left-right direction in FIG. 2). Also, in the present embodiment, the second cover 14 is coupled to the second travel section 11 via a second coupling section 15 so as to be suspended from the second travel section 11. Note that in the present embodiment, portions of the pipe 126 are arranged inside the second cover 14 and inside the second connecting portion 15.

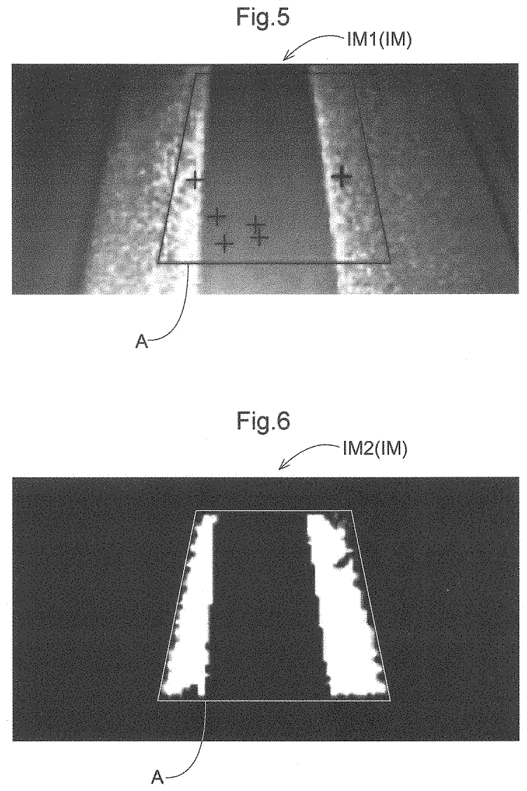

As shown in FIG. 2, each of the cleaning vehicles 1 includes a state detection device 2 that detects a state of the travel route R. In the present embodiment, the state detection device 2 is fixed to the second travel section 11 so as to move together with the second travel section 11. The state detection device 2 is arranged so as to perform detection with respect to a portion of the travel route R that is located on the traveling direction D side of the second travel section 11. In this example, the state detection device 2 is a camera that acquires a captured image IM (see FIGS. 5 and 6) of the travel route R.

The state detection device 2 detects a state of a pre-set inspection region S along the travel route R. As shown in FIG. 1, in the present embodiment, a plurality of inspection ranges S are set along the travel route R. Each of the cleaning vehicles 1 is associated with at least one inspection region S, and detects the state of the associated inspection region S with use of the state detection device 2 while traveling in that inspection region S. In the illustrated example, the travel route R includes a plurality of loop routes, and the inspection regions S are set in one-to-one correspondence with the loop routes.

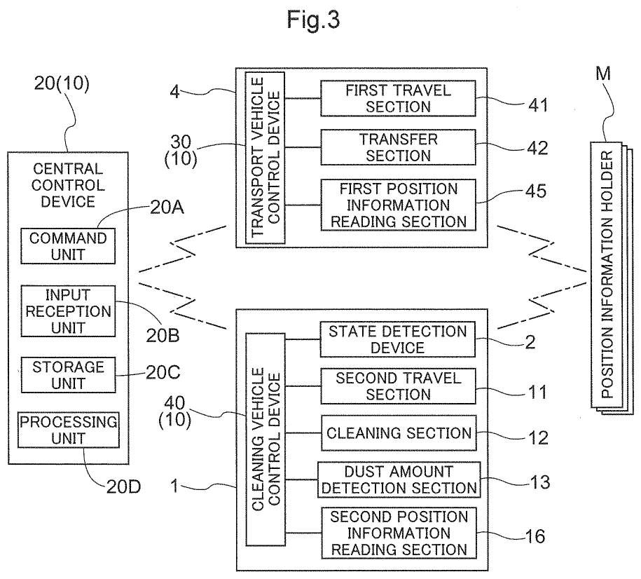

As shown in FIG. 3, in the present embodiment, each of the transport vehicles 4 includes a first position information reading section 45. Also, each of the cleaning vehicles 1 includes a second position information reading section 16. The first position information reading section 45 and the second position information reading section 16 can read position information that is held by position information holders M that are provided at a plurality of locations on or near the rails 3. The position information holders M each hold position information that corresponds to the installation position of the position information holder M. Note that the position information holders M can be configured using a barcode or a wireless tag, for example. If the position information holders M are configured by a barcode, the first position information reading section 45 and the second position information reading section 16 may be configured as a barcode reader. On the other hand, if the position information holders M are configured by a wireless tag, the first position information reading section 45 and the second position information reading section 16 may be configured as a tag reader.

As shown in FIG. 3, the cleaning system 100 includes a control device 10 that controls the cleaning vehicles 1. In the present embodiment, the control device 10 includes a central control device 20, a transport vehicle control device 30 that controls the transport vehicles 4, and a cleaning vehicle control device 40 that controls the cleaning vehicles 1.

The central control device 20 includes a command unit 20A, an input reception unit 20B, a storage unit 20C, and a processing unit 20D.

The command unit 20A outputs commands to the transport vehicle control device 30 and the cleaning vehicle control device 40 to control the devices that such control devices are in charge of.

The input reception unit 20B receives input operations performed by a worker. The input reception unit 20B can be configured using a touch panel display, a keyboard, or a mouse, for example. In the present embodiment, the worker sets the inspection regions S and associates the cleaning vehicles 1 with the inspection regions S via the input reception unit 20B.

The storage unit 20C is configured to store various information necessary for control performed in the cleaning system 100. In the present embodiment, the captured image IM acquired by the state detection device 2 of the cleaning vehicle 1, the position information acquired by the second position information reading section 16 of the cleaning vehicle 1, and the like are stored in the storage unit 20C.

The processing unit 20D is configured to perform predetermined processing on information received via the input reception unit 20B, information stored in the storage unit 20C, and the like. In the present embodiment, the processing unit 20D performs image processing such as grayscale processing and binarization processing on the captured image IM.

The transport vehicle control device 30 is provided in each of the transport vehicles 4. The transport vehicle control device 30 controls operations of the first travel section 41 and the transfer section 42 of the transport vehicle 4 based on commands from the central control device 20. Also, based on position information that is held by the position information holders M and was read by the first position information reading section 45, the transport vehicle control device 30 acquires the position on the travel route R at which the transport vehicle 4 that includes the transport vehicle control device 30 is located. Information indicating the position of the transport vehicle 4 acquired in this way is transmitted from the transport vehicle control device 30 to the central control device 20.

The cleaning vehicle control device 40 is provided in each of the cleaning vehicles 1. The cleaning vehicle control device 40 controls operations of the second travel section 11 and the cleaning section 12 of the cleaning vehicle 1 based on commands from the central control device 20. Furthermore, the cleaning vehicle control device 40 acquires information indicating the amount of dust captured by the filter 124 based on a detection signal from the dust amount detection section 13. Also, based on position information that is held by the position information holders M and was read by the second position information reading section 16, the cleaning vehicle control device 40 acquires the position on the travel route R at which the cleaning vehicle 1 that includes the cleaning vehicle control device 40 is located. Information indicating the position of the cleaning vehicle 1 acquired in this way is transmitted from the cleaning vehicle control device 40 to the central control device 20. Information indicating the amount of dust that was captured may also be transmitted from the cleaning vehicle control device 40 to the central control device 20.

Also, the cleaning vehicle control device 40 acquires information indicating the state of the inspection region S detected by the state detection device 2. The acquired information indicating the state of the inspection region S is transmitted from the cleaning vehicle control device 40 to the central control device 20.

The control device 10 is configured to be able to switch the operation mode of the cleaning vehicle 1. As operation modes, the cleaning vehicle 1 has a cleaning mode in which cleaning is performed and a non-cleaning mode in which cleaning is not performed. In the present embodiment, the traveling speed of the cleaning vehicle 1 in the non-cleaning mode is set higher than the traveling speed of the cleaning vehicle 1 in the cleaning mode.

The control device 10 executes inspection control, specification control, and cleaning control. Inspection control is control for causing the state detection device 2 to detect the state of the inspection region S while the cleaning vehicle 1 is traveling in the non-cleaning mode. Specification control is control for specifying a cleaning required region C, which is a region in which cleaning needs to be performed along the travel route R, based on the state of the inspection region S detected by the state detection device 2 during inspection control. Cleaning control is control for causing the cleaning vehicle 1 to travel in the cleaning required region C in the cleaning mode after completion of inspection control and specification control.

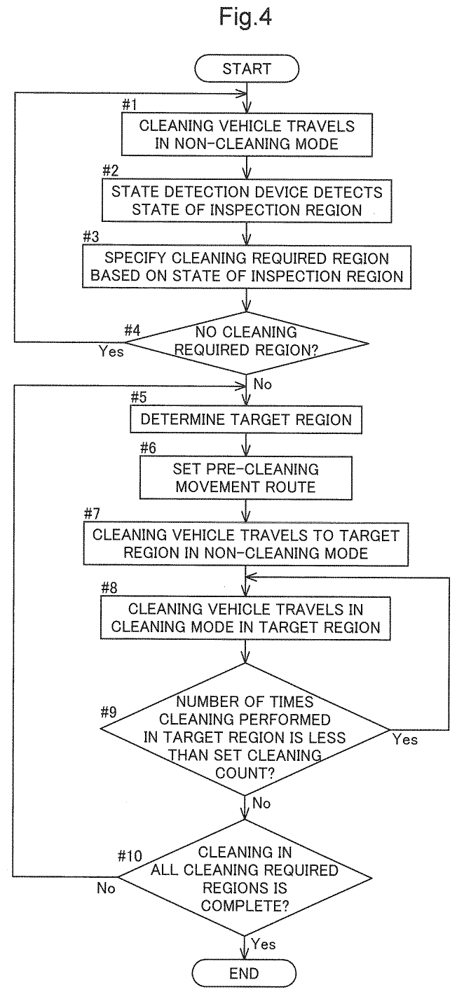

FIG. 4 shows a flowchart illustrating the case where the control device 10 controls one cleaning vehicle 1 associated with one inspection region S, as an example of control processing performed by the control device 10.

As shown in FIG. 4, first, the control device 10 causes the cleaning vehicle 1 to travel in the non-cleaning mode (step #1). The control device 10 then causes the state detection device 2 to detect the state of the inspection region S while the cleaning vehicle 1 travels in the non-cleaning mode (step #2). In this example, via the cleaning vehicle control device 40, the command unit 20A causes the state detection device 2 to capture an image of the travel route R and store the captured image IM in the storage unit 20C in association with position information regarding the cleaning vehicle 1 acquired by the second position information reading section 16. Here, the state detection device 2 can be configured to capture an image of the travel route R at a constant travel distance interval, or capture an image of the travel route R at a constant time interval, for example.

Note that steps #1 and #2 described above correspond to inspection control. In this example, in the inspection control, in order for the cleaning vehicle 1 to travel over the entirety of the travel route R in the inspection region S, the control device 10 performs control so as to prioritize the traveling of the cleaning vehicle 1 in a portion of the travel route R where the cleaning vehicle 1 has not yet traveled. At this time, if the cleaning vehicle 1 is likely to interfere with a transport vehicle 4 or another cleaning vehicle 1, the control device 10 controls the cleaning vehicle 1 to perform an avoidance action to avoid such interference. After performing the avoidance action, the cleaning vehicle 1 may possibly again travel along a portion of the travel route R that has already been traveled during inspection control, but it is sufficient that the cleaning vehicle 1 travels the entirety of the travel route R in the inspection region S.

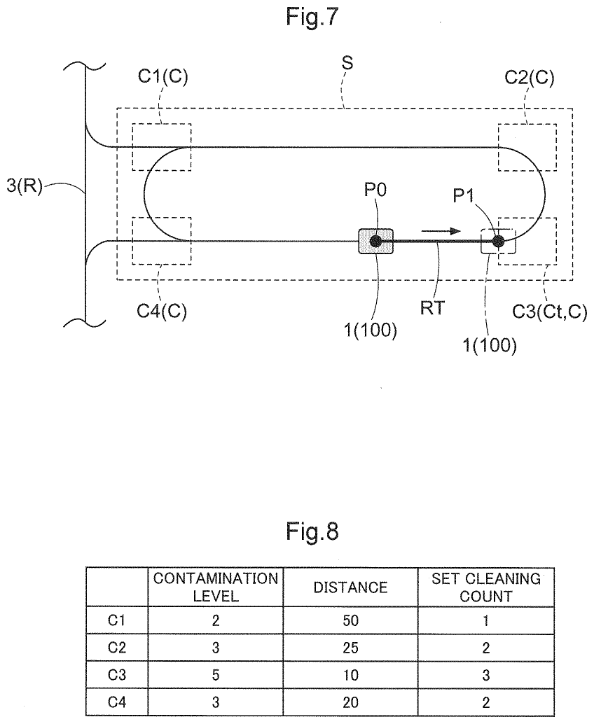

Next, based on the state of the inspection region S detected by the state detection device 2, the control device 10 specifies a cleaning required region C, which is a region in which cleaning needs to be performed along the travel route R (step #3). In this example, first, as shown in FIG. 5, the processing unit 20D acquires a first processed image IM1 by performing grayscale processing on a captured image IM stored in the storage unit 20C. Next, as shown in FIG. 6, the processing unit 20D acquires a second processed image IM2 by performing binarization processing on the first processed image IM1. Then, if the area of a portion in which dust appears (here, the area of a white portion in FIG. 6) exceeds a predetermined threshold value in a predetermined region A in the second processed image IM2, the processing unit 20D determines that the region that corresponds to the captured image IM in the travel route R is a cleaning required region C. In this way, by repeating the above processing for all captured images IM, cleaning required regions C are specified for the entirety of the inspection region S. As shown in FIG. 7, in this example, a first region C1, a second region C2, a third region C3, and a fourth region C4 are specified as cleaning required regions C in one inspection region S. Note that step #3 described above corresponds to specification control.

Subsequently, as shown in FIG. 4, the control device 10 determines whether or not the inspection region S includes a cleaning required region C (step #4). If the inspection region S does not include a cleaning required region C (step #4: Yes), the control device 10 returns to step #1 and executes inspection control and specification control again. On the other hand, if the inspection region S includes a cleaning required region C (step #4: No), the control device 10 determines a target region Ct, which is the cleaning required region C in which the cleaning vehicle 1 is to perform cleaning the soonest at the present time (step #5).

When determining the target region Ct, if the inspection region S includes one cleaning required region C, the control device 10 sets that cleaning required region C as the target region Ct. On the other hand, if the inspection region S includes a plurality of cleaning required regions C (here, the first region C1, the second region C2, the third region C3, and the fourth region C4), the control device 10 determines one of the cleaning required regions C to be the target region Ct based on at least either a contamination level indicating an extent of dirtiness of the cleaning required region C, or the length of a pre-cleaning movement route RT (FIG. 7), which is the route from a completion point P0 where inspection control and specification control end to a cleaning start point P1 where the cleaning required region C starts.

In this example, the control device 10 determines the contamination level of the cleaning required region C as one of multiple levels. For example, the contamination level can be determined based on the area of the portion in which dust appears (here, the area of the white portion in FIG. 6) in the second processed image IM2, which corresponds to the cleaning required region C. In the example shown in FIG. 8, the contamination level is expressed in five levels, and the contamination levels of the first region C1, the second region C2, the third region C3, and the fourth region C4 are determined to be “2”, “3”, “5”, and “3”, respectively.

Also, in this example, the control device 10 calculates the length of the pre-cleaning movement route RT based on position information indicating the completion point P0 and position information indicating the cleaning start point P1, which are acquired by the second position information reading section 16. In the example shown in FIG. 8, the lengths (denoted as “distance” in FIG. 8) of the pre-cleaning movement route RT in the first region C1, the second region C2, the third region C3, and the fourth region C4 are calculated as “50”, “25”, “10”, and “20”, respectively.

When determining the target region Ct based on the contamination levels of the cleaning required regions C, the control device 10 sets the cleaning required region C that has the highest contamination level as the target region Ct. In such a case, in the example shown in FIG. 8, the control device 10 determines the target region Ct to be the third region C3, which has the highest contamination level among the first region C1, the second region C2, the third region C3, and the fourth region C4. In this way, in the case where a plurality of cleaning required regions C are specified in specification control, the control device 10 determines a contamination level, which indicates an extent of dirtiness, from among a plurality of levels for each of the cleaning required regions C, and first executes cleaning control with respect to the cleaning required region C that has the highest contamination level.

Also, in the case where the target region Ct is determined based on the length of the pre-cleaning movement route RT, the control device 10 determines the target region Ct to be the cleaning required region C that has the shortest pre-cleaning movement route RT. In such a case, in the example shown in FIG. 8, the control device 10 determines the target region Ct to be the third region C3, which has the shortest pre-cleaning movement route RT among the first region C1, the second region C2, the third region C3, and the fourth region C4. In this way, in the case where a plurality of cleaning required regions C are specified in specification control, the control device 10 first executes cleaning control with respect to the cleaning required region C that is closest to the point where inspection control and specification control ended (completion point P0).

Note that in the case where the target region Ct is determined based on both the contamination levels of the cleaning required regions C and the lengths of the pre-cleaning movement route RT, the control device 10 determines the length of the pre-cleaning movement route RT from among five levels (the shorter the pre-cleaning movement route RT is, the higher the determined value is), similarly to the contamination level of the cleaning required region C, and determines the target region Ct to be the cleaning required region C that has the highest total value of the determined value and the contamination level of the cleaning required region C, for example. As another example, it is possible to calculate a first weight by multiplying the length of the pre-cleaning movement route RT by a predetermined coefficient, calculate a second weight by multiplying the contamination level of the cleaning required region C by a predetermined coefficient, and determine the target region Ct to be the cleaning required region C that has the highest total value or product value of the first weight and the second weight.

As shown in FIG. 4, after determining the target region Ct (step #5), the control device 10 sets the pre-cleaning movement route RT (see FIG. 7), which is the route from the completion point P0 to the cleaning start point P1 (step #6). At this time, the cleaning start point P1 belongs to the target region Ct. Note that the pre-cleaning movement route RT is set without using the route traveled by the cleaning vehicle 1 during inspection control as a basis. Such a configuration is particularly suitable in the case where, for example, the route from the completion point P0 to the cleaning start point P1 is a complex route that includes more branches and merges than shown in FIG. 7, and multiple routes can be selected as the pre-cleaning movement route RT. With such a configuration, in the case where multiple routes can be selected as the pre-cleaning movement route RT, the cleaning vehicle 1 can be allowed to reach the cleaning start point P1 on the optimum route if consideration is given to avoiding traffic congestion of transport vehicles 4, the length of the pre-cleaning movement route RT, and the like, regardless of the route traveled by the cleaning vehicle 1 during inspection control.

Subsequently, the control device 10 causes the cleaning vehicle 1 to travel along the set pre-cleaning movement route RT in the non-cleaning mode (step #7). The control device 10 then causes the cleaning vehicle 1 to travel in the target region Ct in the cleaning mode (step #8). In other words, the control device 10 causes the cleaning vehicle 1 to perform cleaning in the target region Ct. Note that step #8 described above corresponds to cleaning control.

After the cleaning of the target region Ct performed by the cleaning vehicle 1 is complete, the control device 10 determines whether or not the number of times the cleaning of the target region Ct has been performed is less than the pre-set set cleaning count (step #9). Here, the set cleaning count is set higher as the contamination level of the cleaning required region C increases. In the example shown in FIG. 8, the set cleaning count is set to “1”, “2”, “3”, and “2” in the first region C1, the second region C2, the third region C3, and the fourth region C4, respectively.

If the number of times cleaning has been performed in the target region Ct is less than the set cleaning count (step #9: Yes), the control device 10 returns to step #8 and executes cleaning control again. In this way, in specification control, the control device 10 determines the contamination level, which indicates the extent of dirtiness of the cleaning required region C, from among a plurality of levels, and sets a higher number of times that cleaning control is executed with respect to the cleaning required region C as the contamination level of the cleaning required region C increases. Here, after the cleaning of one target region Ct is complete, the cleaning vehicle 1 travels around the travel route R so as to again arrive at the cleaning start point P1 of the target region Ct, and executes cleaning control in the target region Ct. Note that in the case where the cleaning vehicle 1 passes through another cleaning required region C while traveling around the travel route R in this way, the cleaning vehicle 1 may execute cleaning control in the other cleaning required region C while passing through.

If the number of times that cleaning was performed in the target region Ct has reached the set cleaning count (step #9: No), the control device 10 determines whether or not cleaning in all of the cleaning required regions C is complete (step #10). If cleaning in all of the cleaning required regions C is not complete (step #10: No), the control device 10 returns to step #5 described above, and determines the target region Ct from among the cleaning required regions C in which cleaning is not complete. If cleaning in all of the cleaning required regions C is complete (step #10: Yes), the control device 10 ends control processing.

### OTHER EMBODIMENTS

(1) In the above embodiment, an example is described in which the state detection device 2 is a camera that acquires the captured image IM. However, the present invention is not limited to such a configuration, and as another example, the state detection device 2 may be a device that irradiates the dust accumulation location on the rails 3 with light, and detects the state of the travel route R based on reflected light. As another example, the state detection device 2 may be configured using any of various sensors that detect the state of the travel route R using radio waves or sound waves, or by bringing a probe or the like directly into contact with a target location.

(2) In the above embodiment, an example is described in which the traveling speed of the cleaning vehicle 1 in the non-cleaning mode is set higher than the traveling speed of the cleaning vehicle 1 in the cleaning mode. However, the present invention is not limited to such a configuration, and the traveling speed of the cleaning vehicle 1 in the non-cleaning mode may be the same as the traveling speed of the cleaning vehicle 1 in the cleaning mode. Also, the traveling speed of the cleaning vehicle 1 in the non-cleaning mode may be lower than the traveling speed of the cleaning vehicle 1 in the cleaning mode.

(3) In the above-described embodiment, an example is described in which the pre-cleaning movement route RT is set without using the route traveled by the cleaning vehicle 1 during inspection control as a basis. However, the present invention is not limited to such a configuration, and the pre-cleaning movement route RT may be set along the route traveled by the cleaning vehicle 1 during inspection control.

(4) In the above-described embodiment, an example is described in which if it is determined in specification control that the inspection region S does not include a cleaning required region C, inspection control and specification control are executed again. However, the present invention is not limited to such a configuration, and control processing may be ended if it is determined in specification control that the inspection region S does not include a cleaning required region C.

(5) In the above embodiment, an example is described in which if a plurality of cleaning required regions C are specified in specification control, the contamination level, which indicates the extent of dirtiness, is determined from among a plurality of levels for each of the cleaning required regions C, and the target region Ct is determined to be the cleaning required region C that has the highest contamination level. Also, in the above embodiment, an example is described in which if a plurality of cleaning required regions C are specified in specification control, the target region Ct is determined to be the cleaning required region C that is closest to the point where inspection control and specification control ended (completion point P0). However, the present invention is not limited to such configurations, and any one of a plurality of cleaning required regions C may be randomly determined to be the target region Ct, for example.

(6) In the above embodiment, an example is described in which the set cleaning count is set higher as the contamination level in the cleaning required region C increases. However, the present invention is not limited to such a configuration, and a certain set cleaning count may be set regardless of the contamination level in the cleaning required region C, for example. Note that a configuration is possible in which the set cleaning count is 1, that is to say, a configuration is possible in which cleaning is not repeatedly performed in the cleaning required region C.

(7) In the above embodiment, an example is described in which the cleaning system 100 is applied to the article transport facility F that includes the rails 3 suspended from the ceiling. However, the present invention is not limited to such a configuration, and the article transport facility F to which the cleaning system 100 is applied may include rails 3 provided on the floor surface, for example.

(8) In the above embodiment, an example is described in which the cleaning vehicle 1 is configured to clean dust that has accumulated on the rails 3, but the present invention is not limited to this. For example, in some cases, a power supply line for supplying power to the transport vehicles 4 may be arranged along the travel route R. In this case, the cleaning vehicles 1 may be configured to clean dust adhering to the power supply line. Alternatively, the cleaning vehicles 1 may be configured to clean both dust that has accumulated on the rails 3 and dust adhering to the power supply line. Note that in the case where the cleaning vehicle 1 cleans dust adhering to the power supply line, it is preferable that the suction nozzle 121 is provided so as to face the power supply line. In other words, the suction nozzle 121 is provided so as to face the dust accumulation location on the travel route R. Similarly, the brush member 125 is also provided so as to come into contact with the dust accumulation location on the travel route R.

(9) Note that the configurations disclosed in the above embodiments can also be applied in combination with configurations disclosed in other embodiments as long as no contradiction arises. Regarding other configurations as well, the embodiments disclosed in this specification are merely examples in all respects. Accordingly, various modifications can be made as appropriate without departing from the scope of the present disclosure.

### Overview of Embodiments

Below, an overview of the cleaning system described above will be described.

A cleaning system according to an aspect includes:

a cleaning vehicle configured to travel along a predetermined travel route and clean the travel route; and

a control device configured to control the cleaning vehicle,

wherein the cleaning vehicle includes a state detection device configured to detect a state of the travel route, and has, as operation modes, a cleaning mode in which the cleaning is performed and a non-cleaning mode in which the cleaning is not performed, and

the control device is configured to execute:
an inspection control of causing the state detection device to detect a state of a pre-set inspection region along the travel route while causing the cleaning vehicle to travel in the non-cleaning mode;
a specification control of specifying a cleaning required region, which is a region in which the cleaning needs to be performed in the travel route, based on the state of the inspection region detected by the state detection device in the inspection control; and
a cleaning control of causing the cleaning vehicle to travel in the cleaning mode in the cleaning required region after the inspection control and the specification control end.

According to this configuration, the state of the pre-set inspection region along the travel route is detected by the state detection device provided in the cleaning vehicle. A cleaning required region, which is a region in which cleaning needs to be performed along the travel route, is specified based on the state of the inspection region detected by the state detection device, and the cleaning vehicle is caused to perform cleaning in the cleaning required region. This eliminates the need for a worker to identify a cleaning required region visually, for example, or manually set the region to be cleaned by the cleaning vehicle. Accordingly, the cleaning performed by the cleaning vehicle can be performed automatically and efficiently.

Here, it is preferable that the control device sets a traveling speed of the cleaning vehicle in the non-cleaning mode higher than a traveling speed of the cleaning vehicle in the cleaning mode.

According to this configuration, it is possible to shorten the time required for inspection control in which the state detection device detects the state of the inspection region along the travel route by while the cleaning vehicle travels in the non-cleaning mode. Here, the inspection region is generally larger than the cleaning required region. For this reason, by shortening the time required for inspection control as described above, it is possible to effectively shorten the time from the start of inspection control to the end of cleaning control.

Also, it is preferable that after the inspection control and the specification control end, the control device sets a pre-cleaning movement route, which is a route from a point where the inspection control and the specification control ended to a start point of the cleaning required region, without using a route traveled by the cleaning vehicle in the inspection control as a basis, and causes the cleaning vehicle to travel in the non-cleaning mode along the pre-cleaning movement route.

According to this configuration, a route that enables efficiently arriving at the start point of the cleaning required region can be set as the pre-cleaning movement route without using the route traveled by the cleaning vehicle during inspection control as a basis. Accordingly, cleaning control can be quickly started after the completion of inspection control and specification control.

Also, it is preferable that the control device, in response to determining during the specification control that the inspection region does not include the cleaning required region, executes the inspection control and the specification control again.

According to this configuration, if there is no need to perform cleaning, inspection control and specification control are repeatedly executed until cleaning needs to be performed. As a result, when the need to perform cleaning arises, cleaning can be started quickly.

Also, it is preferable that the control device, in response to specifying a plurality of cleaning required regions in the specification control, determines a contamination level, which indicates an extent of dirtiness, from among a plurality of levels for each of the cleaning required regions, and first executes the cleaning control in a cleaning required region having a highest contamination level.

According to this configuration, if a plurality of cleaning required regions are identified, it is possible to preferentially perform cleaning in a cleaning required region that has a higher contamination level. Accordingly, it is possible to efficiently perform cleaning with respect to a plurality of cleaning required regions.

Also, it is preferable that in the specification control, the control device determines a contamination level indicating an extent of dirtiness of the cleaning required region from among a plurality of levels, and sets a higher number of times that the cleaning control is executed with respect to the cleaning required region as the contamination level of the cleaning required region increases.

According to this configuration, even if the contamination level in the cleaning required region is high, dust in the cleaning required region can be appropriately removed. In other words, it is possible to effectively reduce the contamination level in a cleaning required region that has a high contamination level.

Also, it is preferable that the control device, in response to specifying a plurality of cleaning required regions in the specification control, first executes the cleaning control with respect to a cleaning required region closest to a point where the inspection control and the specification control ended.

According to this configuration, if a plurality of cleaning required regions are specified, it is possible to select a cleaning required region that can be reached in a short period of time, and quickly start cleaning.

Also, it is preferable that in the inspection control, in order for the cleaning vehicle to travel over an entirety of the travel route in the inspection region, the control device performs control to prioritize traveling of the cleaning vehicle in a portion of the travel route where the cleaning vehicle has not yet traveled.

According to this configuration, in inspection control, even if the cleaning vehicle performs an avoidance action to avoid interference with a transport vehicle or another cleaning vehicle, and thus deviates from the route that was determined before the avoidance action, it is easy to cause the cleaning vehicle to travel over the entirety of the travel route in the inspection region.

### INDUSTRIAL APPLICABILITY

The technology according to the present disclosure is applicable to a cleaning system that includes a cleaning vehicle that travels along a defined travel route and cleans the travel route.

What is claimed is:

1. A cleaning system comprising:
a cleaning vehicle configured to travel along a predetermined travel route and clean the travel route; and
a control device configured to control the cleaning vehicle,
wherein the cleaning vehicle comprises a state detection device configured to detect a state of the travel route and has, as operation modes, a cleaning mode in which the cleaning is performed and a non-cleaning mode in which the cleaning is not performed, and
wherein the control device is configured to execute:
an inspection control for causing the state detection device to detect a state of a pre-set inspection region along the travel route while causing the cleaning vehicle to travel in the non-cleaning mode;
a specification control for specifying a cleaning required region, which is a region in which the cleaning needs to be performed in the travel route, based on the state of the inspection region detected by the state detection device in the inspection control; and
a cleaning control for causing the cleaning vehicle to travel in the cleaning mode in the cleaning required region after the inspection control and the specification control end.

2. The cleaning system according to claim 1,
wherein the control device sets a traveling speed of the cleaning vehicle in the non-cleaning mode higher than a traveling speed of the cleaning vehicle in the cleaning mode.

3. The cleaning system according to claim 1,
wherein after the inspection control and the specification control end, the control device sets a pre-cleaning movement route, which is a route from a point where the inspection control and the specification control ended to a start point of the cleaning required region, without using a route traveled by the cleaning vehicle in the inspection control as a basis, and causes the cleaning vehicle to travel in the non-cleaning mode along the pre-cleaning movement route.

4. The cleaning system according to claim 1,
wherein the control device, in response to determining during the specification control that the inspection region does not include the cleaning required region, executes the inspection control and the specification control again.

5. The cleaning system according to claim 1,
wherein the control device, in response to specifying a plurality of cleaning required regions in the specification control, determines a contamination level, which indicates an extent of dirtiness from among a plurality of levels for each of the cleaning required regions, and first executes the cleaning control in a cleaning required region having a highest contamination level.

6. The cleaning system according to claim 1,
wherein in the specification control, the control device determines a contamination level indicating an extent of dirtiness of the cleaning required region from among a plurality of levels, and sets a higher number of times that the cleaning control is executed with respect to the cleaning required region as the contamination level of the cleaning required region increases.

7. The cleaning system according to claim 1,
wherein the control device, in response to specifying a plurality of cleaning required regions in the specification control, first executes the cleaning control with respect to a cleaning required region closest to a point where the inspection control and the specification control ended.

8. The cleaning system according to claim 1,
wherein in the inspection control, in order for the cleaning vehicle to travel over an entirety of the travel route in the inspection region, the control device performs control to prioritize traveling of the cleaning vehicle in a portion of the travel route where the cleaning vehicle has not yet traveled.
